(19) United States
(12) Patent Application Publication
(10) Pub. No.: US 2023/0363177 A1
(43) Pub. Date: Nov. 9, 2023

(54) FERAM DEVICE AND METHOD OF MANUFACTURING

(71) Applicant: Taiwan Semiconductor Manufacturing Company, Hsinchu (TW)

(72) Inventors: Yu Chao Lin, Hsinchu (TW); Jung-Piao Chiu, Kaohsiung (TW); Chih-Sheng Chang, Hsinchu (TW); Yuan-Tien Tu, Puzih (TW)

(21) Appl. No.: 17/737,308

(22) Filed: May 5, 2022

(51) Int. Cl. H01L 27/11507

(52) U.S. Cl. CPC H01L 27/11507

(57) ABSTRACT

Manufacture of a ferroelectric random-access memory device includes forming a first electrode and an intermetal dielectric (IMD) layer over the first electrode. The IMD layer has a first surface on a first side of the IMD layer distal from the first electrode and a second surface on a second side of the IMD layer proximate to the first electrode. A via is created through the IMD layer, which is aligned with the first electrode underneath and has a side wall extending from the first surface of the IMD layer to the second surface of the IMD layer. A ferroelectric layer is deposited over the IMD layer. The ferroelectric layer includes a first part within the via and a second part extending laterally out from the via over the first surface of the IMD layer, the second part thereafter being removed by chemical mechanical polishing.

### BACKGROUND

The following relates to the semiconductor arts, and in particular, to a Ferroelectric Random-Access Memory (FeRAM) device and/or method of manufacturing the same.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features as shown in the accompany figures may be arbitrarily increased or reduced for clarity of discussion.

FIG. 1 diagrammatically illustrates a cross-section view of a FeRAM cell in accordance with some embodiments disclosed herein.

FIG. 2 diagrammatically illustrates a cross-section view of a Ferroelectric Memory Field-Effect Transistor (FeMFET) device in accordance with some embodiments disclosed herein.

FIG. 3 is a flow chart showing a method of manufacturing a FeRAM device in accordance with some embodiments disclosed herein.

FIGS. 4A through 4G show cross-section views of a FeRAM cell construction at various stages of a manufacturing process in accordance with some suitable embodiments disclosed herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “left,” “right,” “side,” “back,” “rear,” “behind,” “front,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, a Ferroelectric Random-Access Memory (FeRAM) device is disclosed herein that has a Metal/Ferroelectric/Metal (MFM) layer structure including a ferroelectric layer arranged between top and bottom electrodes. The FeRAM device is a type of non-volatile Random-Access Memory (RAM) that is configured to store data values based on a process of reversible switching between polarization states which occurs due to the ferroelectric characteristic, namely that the crystal structure of the ferroelectric layer is capable of changing when an electric field is present. For example, in a FeRAM cell, when a first voltage bias (for example, a negative voltage bias) is applied to the ferroelectric layer, atoms of the ferroelectric layer may be induced to shift into a first crystal structure orientation, which has a first resistance indicating a first data value (for example, a logical ‘1’), whereas when a second different voltage bias (for example, a positive voltage bias) is applied to the ferroelectric layer, atoms of the ferroelectric layer may be induced to shift into a second crystal structure orientation (different from the first orientation), which has a second resistance (different than the first resistance) indicating a second data value (for example, a logical ‘0’).

FeRAM devices have a number of advantages. Being significantly resistant to power disruption and/or magnetic interference, the FeRAM is a typically a reliable non-volatile memory. The FeRAM can exhibit low power usage, fast write performance, a high maximum read/write endurance, and/or long data retention times. In some suitable embodiments, the FeRAM device disclosed herein includes a Tantalum Nitride (TaN) (or other like suitable material) barrier layer which contacts and/or otherwise connects with a Hafnium-Zirconium Oxide (HfZrO or HZO) (or other like suitable ferroelectric material) layer to achieve an advantage and/or improvement in the Metal-Insultor-Metal (MIM) capacitor storage amount. Suitably, a sufficiently large contact area, for example, along and/or including with via sidewall(s), may be established to provide an advantageous improvement in MIM capacitor performance.

In some non-limiting illustrative embodiments, a FeRAM cell is manufactured at a bottom electrode, for example, in a Back-End Of Line (BEOL) process flow, and control is achieved by way of a drain mode or interconnect to drain mode of operation, for example, as opposed to a gate control and/or with a Front-End Of Line (FEOL) transistor. In some non-limiting illustrative embodiments, during the manufacturing process, the HZO (or other suitable ferroelectric material) layer or film is not patterned or etched, for example, using a dry plasma etching technique or the like. Rather, chemical mechanical polishing (MCP) is employed to remove the HZO (or other suitable ferroelectric material) layer or film down to an Inter-Metal Dielectric (IMD) or oxide layer. This has the advantage of avoiding potential damage and/or drawbacks which might otherwise be caused and/or encountered by the use a dry plasma or other like etching process, for example, including but not limited to, oxidation, halogenation, HK-polymer (for example, HfOx based) and/or other unwanted residue and/or polymer by-product remaining after the etch, etc.

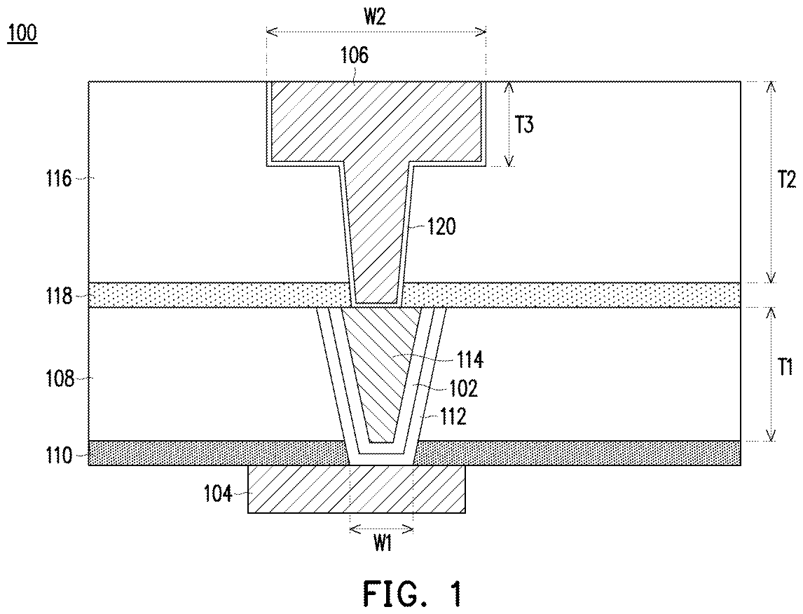

FIG. 1 shows a FeRAM cell 100 in accordance with some non-limiting illustrative embodiments disclosed herein. As shown, the FeRAM cell 100 includes a ferroelectric layer 102 arranged between a bottom electrode 104 and a top electrode 106. In non-limiting illustrative embodiments, the ferroelectric layer 102 may be formed from a suitable ferroelectric material, for example, such as HZO, zirconium oxide (ZrOx), barium titanate (BaTiO₃), combination thereof or the like. In some illustrative examples herein, the ferroelectric layer 102 is HZO. In some non-limiting illustrative embodiments, the ferroelectric layer 102 has a thickness of less than about 50 angstroms (Å). In some non-limiting illustrative embodiments, the ferroelectric layer 102 has a thickness of less than or equal 5 nm, although embodiments in which the ferroelectric layer has a larger thickness than this are also contemplated.

In some non-limiting illustrative embodiments, the bottom electrode 104 may be formed from a metal or other like suitable material, for example, such as copper (Cu), aluminum copper (AlCu), titanium nitride (TiN), tungsten (W), ruthenium (Ru), combinations and/or alloys thereof or the like. Similarly, the top electrode 106 may likewise be formed from a metal or other like suitable material, for example, such as copper (Cu), aluminum copper (AlCu), titanium nitride (TiN), tungsten (W), ruthenium (Ru), combinations and/or alloys thereof or the like. While generally referred to herein as electrodes, it is to be appreciated that the bottom and top electrodes 104, 106 may either or both serve the roles of and/or act as either or both interconnects and/or electrodes. Moreover, it is contemplated for the bottom and top electrodes 104, 106 to be made of the same material, or of different materials.

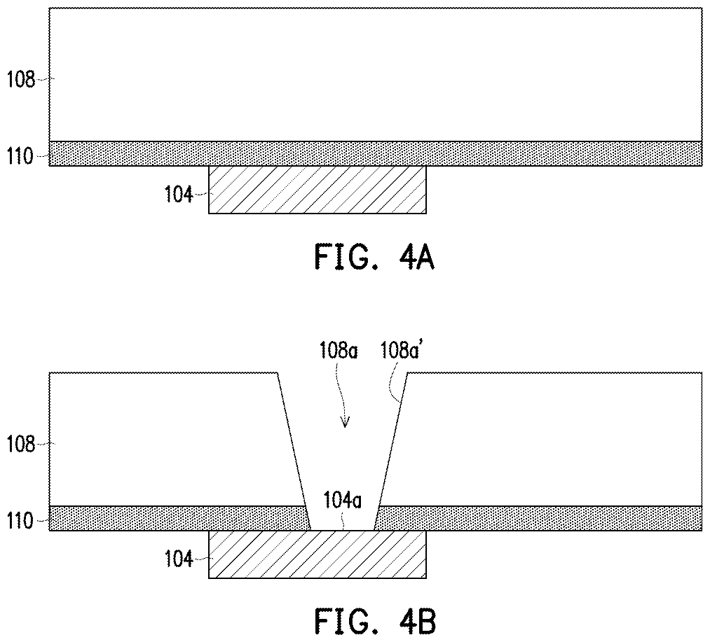

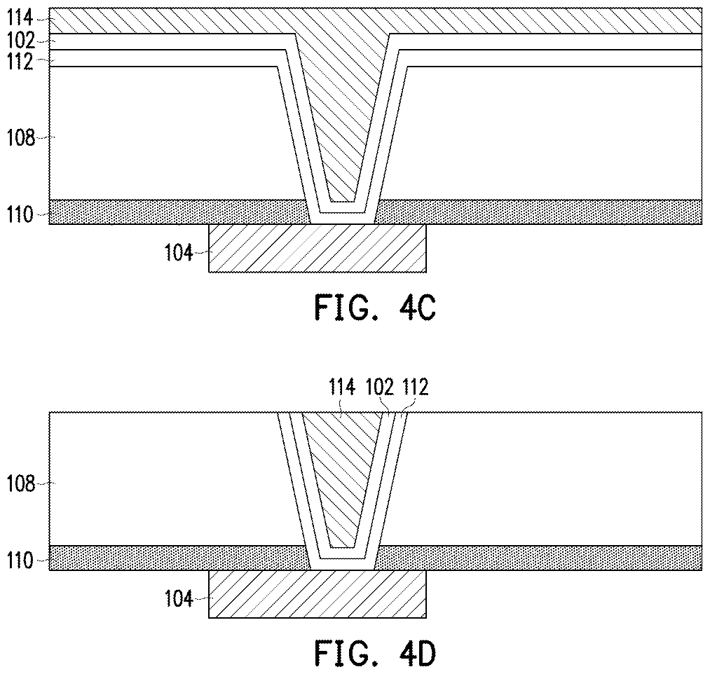

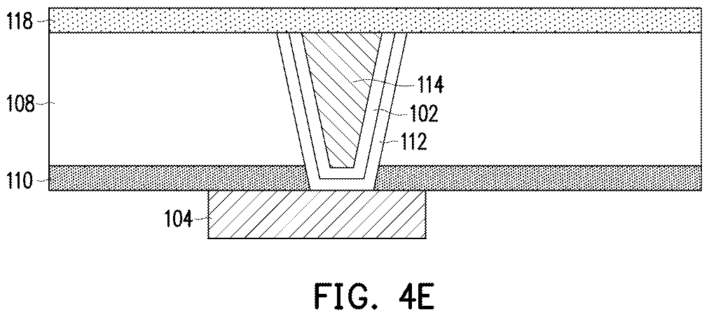

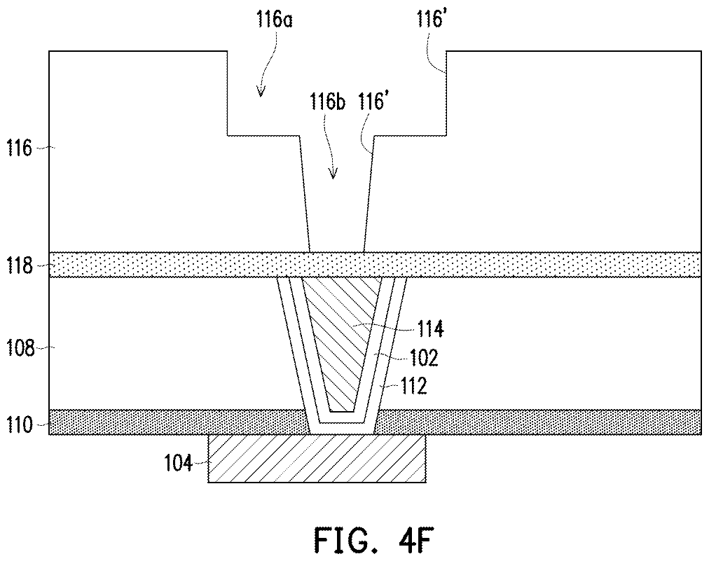

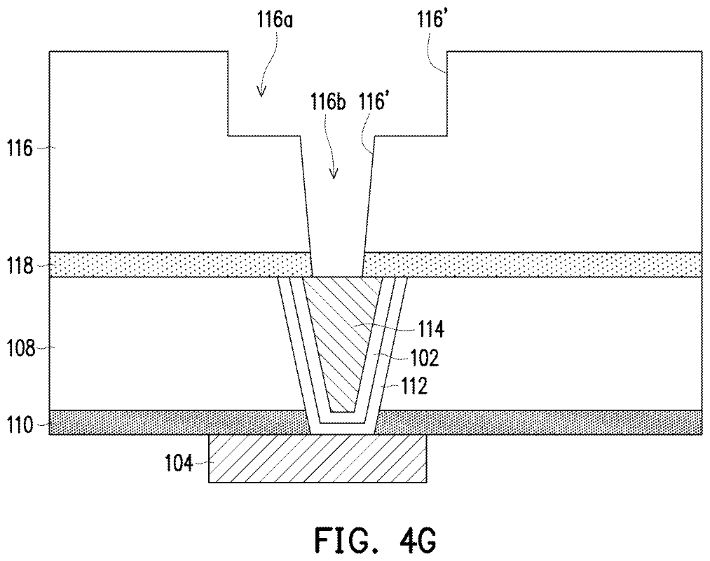

In some non-limiting illustrative embodiments, the ferroelectric layer 102 is formed, situated and/or arranged within an opening, hole or via 108a or the like (for example, as indicated and/or seen in FIG. 4B) formed in and/or extending horizontally through a thickness of an Inter-Metal Dielectric (IMD) or oxide (OX) layer 108. In practice, the IMD or OX layer 108 may be formed from a suitable IMD or OX material, for example, such as a Chemical Vapor Deposition (CVD) oxide, a thermal oxide or other suitable low-k material, combinations thereof or the like. In general, a low-k material refers to a suitable insulating dielectric material or the like with a low dielectric constant (k). In some suitable embodiments, the IMD or OX layer 108 may have a height or thickness T1 (for example, above the bottom electrode 104) in a range between about 80 nanometers (nm) and about 120 nm, inclusive. The IMD or OX layer 108 may be deposited by CVD or any other suitable material deposition technique.

As shown, a first etch stop layer (ESL) 110 may be employed (for example, during the manufacturing process) and/or formed or otherwise situated (at least partially) between the bottom electrode 104 and the IMD or OX layer 108. In some suitable embodiments, the first ESL 110 may be formed from a suitable material, for example, such as silicon nitride (SiN), silicon carbide (SiC), aluminum oxide (AlOₓ), aluminum nitride (AlN), combination thereof or the like.

In some suitable embodiments, as shown in FIG. 1, a first barrier metal or other like material layer 112 may be formed, situated and/or otherwise arranged between the ferroelectric layer 102 and the side wall(s) 108a′ of the via 108a (for example, as indicated and/or seen in FIG. 4B). Further, as shown in FIG. 1, the first barrier metal layer 112 may be interposed between the ferroelectric layer 102 and the bottom electrode 104, while contacting an upper surface of the of the bottom electrode 104, for example, through an opening formed in the first ESL 110 over the bottom electrode 104. Suitably, the opening through which the first barrier metal layer 112 contacts the upper surface of the bottom electrode 104 (i.e., the contact area between the upper surface of the bottom electrode 104 and the first barrier metal layer 112) has a lateral width (also referred to nominally and/or known as a critical dimension (CD)) W1 which ranges between about 20 nm and about 50 nm, inclusive, although values of W1 outside this range are also contemplated. In some suitable embodiments, the first barrier metal layer 112 may be formed from a metal or other like suitable material, for example, such as tantalum (Ta), tantalum nitride (TaN), ruthenium (Ru), titanium (Ti), titanium nitride (TiN), tungsten nitride (WN), cobalt (Co), combinations and/or alloys thereof or the like. In a non-limiting illustrative embodiment, the first barrier metal layer 112 may have a thickness of about 30 Å (i.e. 3 nm), other thicknesses are contemplated.

As shown in FIG. 1, a remainder of the hole or via 108a (for example, as indicated and/or seen in FIG. 4B) may be filled with a suitable metal or other electrically conductive material layer 114. For example, the layer 114 filling the remainder of the hole or via 108a may be formed from a metal or other electrically conductive material, for example, such as titanium nitride (TiN), tungsten (W), combinations and/or alloys thereof or the like.

In some non-limiting illustrative embodiments, as shown in FIG. 1, the top electrode 106 is formed, situated and/or arranged within an opening or the like formed in a low-k material layer 116. In practice, the low-k material layer may be a SiOC material (for example, a silicon oxide material with a rich carbon dopant) or a second IMD or OX layer and/or may be formed from a suitable IMD or OX material, for example, such as a Chemical Vapor Deposition (CVD) oxide, a thermal oxide or other suitable low-k material, combinations thereof or the like. The IMD or OX layer 116 may be deposited by CVD or any other suitable material deposition technique. As indicated and/or seen in FIGS. 4F and 4G, the opening in which the top electrode 106 is formed, situated and/or otherwise arranged may include a laterally extending region, portion or trench 116a at an upper end or side of the low-k material layer 116 and a hole or via 116b or the like extending horizontally through a depth or thickness of the low-k material layer 116. In some suitable embodiments, the low-k layer 116 may have a height or thickness T2 indicated in FIG. 1, which may in some non-limiting illustrative embodiments be in a range between about 150 nanometers (nm) and about 250 nm, inclusive. Suitably, the trench 116a (for example, as indicated and/or seen in FIGS. 4F and 4G) has a lateral width (also referred to nominally and/or known as a CD) W2 which ranges between about 100 nm and about 300 nm, inclusive. Suitably, the trench 116a (for example, as indicated and/or seen in FIGS. 4F and 4G) may have a depth or thickness T3 in a range of between about 50 nm and 80 nm, inclusive. These are merely non-limiting illustrative examples, and other dimensions for these features are contemplated.

As shown in FIG. 1, a second etch stop layer (ESL) 118 may be employed (for example, during the manufacturing process) and/or formed or otherwise situated between the IMD or OX layer 108 and the low-k material layer 116. In some suitable embodiments, the second ESL 118 may be formed from a suitable material, for example, such as silicon nitride (SiN), silicon carbide (SiC), aluminum oxide (AlOx), aluminum nitride (AlN), combination thereof or the like.

In some suitable embodiments, as shown in FIG. 1, a second barrier metal or other like material layer 120 may be formed, situated and/or otherwise arranged between the top electrode 106 and the wall(s) and/or side(s) 116′ of the trench 116a and/or via 116b (for example, as indicated and/or seen in FIGS. 4F and 4G). Further, as shown in FIG. 1, the second barrier metal layer 120 may be interposed between the electrically conductive material layer 114 and the top electrode 106, while contacting an upper surface 114a of the layer 114, for example, through an opening formed in the second ESL 118 over the layer 114. This provides an electrically conductive path from the electrically conductive material layer 114 to the top electrode 106. In some non-limiting illustrative embodiments, the second barrier metal layer 120 may be formed from a metal or other like suitable material, for example, such as tantalum (Ta), tantalum nitride (TaN), ruthenium (Ru), titanium (Ti), titanium nitride (TiN), tungsten nitride (WN), cobalt (Co), combinations and/or alloys thereof or the like. In a non-limiting illustrative embodiment, the second barrier metal layer 120 may have a thickness of about 30 Å (i.e. 3 nm), although other thickness values are contemplated.

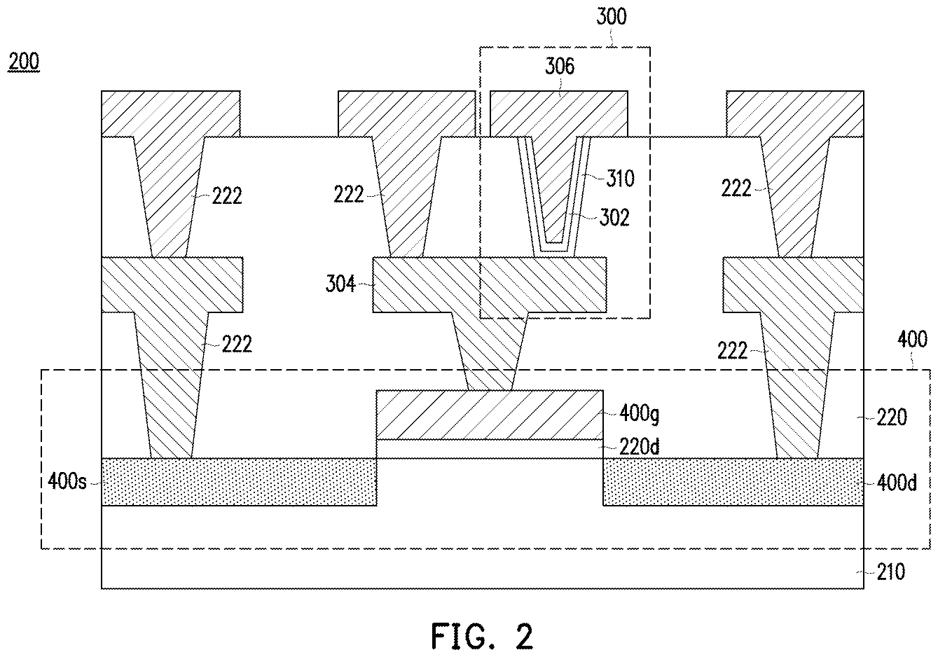

FIG. 2 shows a Ferroelectric Memory Field-Effect Transistor (FeMFET) device 200 in accordance with some suitable embodiments disclosed herein. As shown, the FeMFET device 200 includes a FeRAM cell 300 coupled to an access or other like transistor 400, for example, a Field-Effect Transistor (FET). As a non-limiting illustrative example, the FeRAM cell 300 could comprise the FeRAM cell 100 of FIG. 1.

In some suitable embodiments, the access transistor 400 comprises a drain region 400d and a source region 400s formed or otherwise established within a semiconductor substrate 210. Between the drain region 400d and the source region 400s and above the substrate 210, is a gate electrode 400g. A gate dielectric layer 400d separates the gate electrode 400g from the substrate 210. A dielectric structure 220 is arranged over the substrate 210 and surrounds various interconnects, interconnect wires and/or vias.

As shown in FIG. 2, a ferroelectric layer 302 (for example, corresponding and/or similar to the ferroelectric layer 102 shown in the embodiment of FIG. 1) is formed, situated and/or otherwise arranged between a bottom electrode 304 and a top electrode 306 of the FeRAM cell 300 to establish a Metal/Ferroelectric/Metal (MFM) capacitor or like structure. Suitably, the bottom electrode 304 (for example, corresponding and/or similar to the bottom electrode 104 shown in the embodiment of FIG. 1) may be formed from a metal or other like suitable material, for example, such as copper (Cu), aluminum copper (AlCu), titanium nitride (TiN), tungsten (W), ruthenium (Ru), combinations and/or alloys thereof or the like. Similarly, the top electrode 306 (for example, corresponding and/or similar to the top electrode 106 shown in the embodiment of FIG. 1) may likewise be formed from a metal or other like suitable material, for example, such as copper (Cu), aluminum copper (AlCu), titanium nitride (TiN), tungsten (W), ruthenium (Ru), combinations and/or alloys thereof or the like. While generally referred to herein as electrodes, it is to be appreciated that the bottom and top electrodes 304, 306 may either or both serve the roles of and/or act as either or both interconnects and/or electrodes. In some suitable embodiments, the ferroelectric layer 302 may be formed from a suitable ferroelectric material, for example, such as HZO, zirconium oxide (ZrOx), barium titanate (BaTiO₃), combination thereof or the like. In some non-limiting illustrative embodiments, the ferroelectric layer 302 has a thickness of less than about 50 Å (i.e. 5 nm), although larger thickness values are contemplated.

In some non-limiting illustrative embodiments, the ferroelectric layer 302 is formed, situated and/or arranged within a hole or via or the like formed in and/or extending horizontally through a thickness of the dielectric structure 220. In practice, the dielectric structure 220 may be formed from one or more layers of suitable IMD or OX material or electrically insulating material, for example, such as Chemical Vapor Deposition (CVD) oxides, thermal oxides or other suitable low-k material, combinations thereof or the like.

In some non-limiting illustrative embodiments, as shown in FIG. 2, a barrier metal or other like material layer 310 (for example, corresponding and/or similar to the first barrier metal layer 112 shown in the embodiment of FIG. 1) may be formed, situated and/or otherwise arranged between the ferroelectric layer 302 and the side wall(s) of the via in which the ferroelectric layer 302 is formed and/or resides. Further, as shown in FIG. 2, the barrier metal layer 310 may be interposed between the ferroelectric layer 302 and the bottom electrode 304, while contacting an upper surface of the of the bottom electrode 304. In some non-limiting illustrative embodiments, the barrier metal layer 310 may be formed from a metal or other like suitable material, for example, such as tantalum (Ta), tantalum nitride (TaN), ruthenium (Ru), titanium (Ti), titanium nitride (TiN), tungsten nitride (WN), cobalt (Co), combinations and/or alloys thereof or the like. In some non-limiting illustrative embodiments, the barrier metal layer 310 may have a thickness of about 30 Å (i.e. 3 nm), although other thicknesses are contemplated.

As shown in FIG. 2, in some embodiments, the bottom electrode 304 of the FeRAM cell 300 may be coupled to and/or in operative electrical communication with (for example, by way of a suitable interconnect or via or otherwise) the gate electrode 400g of the access transistor 400. In some suitable embodiments, various electrically conductive interconnects, interconnect wires and/or vias (collectively and/or individually indicated by reference numeral 222) are formed on, in and/or through the dielectric structure 220 to provide respective electrical access and/or connections to the drain region 400d, source region 400s and gate electrode 400g of the access transistor 400.

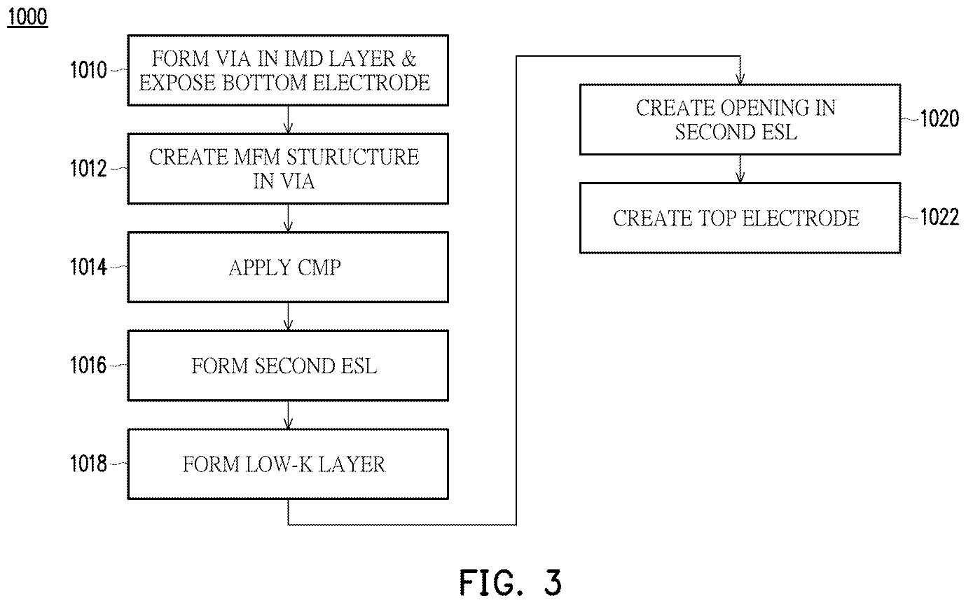

With reference now to FIG. 3, there is shown a flow chart illustrating selected steps in a method and/or process 1000 for manufacturing a FeRAM cell, for example, such as the FeRAM cell 100 illustrated in FIG. 1. FIGS. 4A through 4G show the configurations and/or progressive states of the FeRAM cell construction at various stages of the manufacturing process 1000.

FIG. 4A shows the configuration and/or state of the FeRAM cell construction at the start or beginning of the illustrated manufacturing process 1000 shown in FIG. 3. As shown in FIG. 4A, the bottom electrode 104 already has the first ESL 110 provided, formed, deposited or otherwise arranged thereover, and the IMD or OX layer 108 is already provided, formed, deposited or otherwise arranged over the first ESL 110. Such a starting construction may be achieved or realized, for example, at the start of BEOL processing, by way of any appropriate and/or suitable FEOL and/or Middle-End Of Line (MEOL) processing steps or the like that may have been executed, including one or more process steps to create an access or other suitable FET, for example, in the case of a FeMFET such as or like the one illustrated in FIG. 2. However, for simplicity herein, selected structures, layers, devices and/or the like, for example, formed during the FEOL manufacturing process are not shown in FIGS. 4A through 4G.

In a first step 1010 of the manufacturing process 1000 illustrated in FIG. 3, the upper surface 104a of the bottom electrode 104 is exposed through the IMD or OX layer 108 and the first ESL 110. For example, in some suitable embodiments, a hole or via 108a or the like is formed in the IMD or OX layer 108 over and/or above the bottom electrode 104, for example, using a suitable photolithography process employing an appropriate mask and etching or other like material removal technique. As indicated and/or seen, for example, in FIG. 4B, the hole or via 108a may have and/or be defined by side wall(s) 108a′. In some suitable embodiments, step 1010 may further include, for example, a sub-step (or an additional step may be performed after step 1010), in which a further etch or other like material removal technique may be executed to open a hole and/or opening in the first ESL 110 beneath the via 108a and over and/or above the bottom electrode 104, thereby exposing the upper surface 104a of the bottom electrode 104. Accordingly, the configuration or state of the FeRAM cell construction following step 1010 is shown in FIG. 4B.

In some suitable embodiments, at a next step 1012, a Metal/Ferroelectric/Metal (MFM) structure is created in the hole or via 108a formed in the IMD or OX layer 108. For example, step 1012 may include successively: (i) depositing, growing and/or otherwise forming the first barrier metal layer 112 covering and/or over the IMD or OX layer 108; (ii) depositing, growing and/or otherwise forming the ferroelectric layer 102 covering and/or over the first barrier metal layer 112; and thereafter, (iii) applying a metallization or other like technique to form the layer 114, for example, filling a remainder of the hole or via 108a. Accordingly, the configuration or state of the FeRAM cell construction following step 1012 is shown in FIG. 4C. As shown, at this stage, in addition to covering the side wall(s) 108a′ of the via 108a and the exposed upper surface 104a of the bottom electrode 104, the first barrier metal layer 112 extends laterally over and/or covers a top surface 108′ of the IMD or OX layer 108. Similarly, the subsequently deposited and/or otherwise formed ferroelectric layer 102 extends laterally outside the via 108a and above the top surface 108′ of the IMD or OX layer 108; and, in addition to filling a remainder of the hole or via 108a, the layer 114 also extends laterally outside the via 108a and above the top surface 108′ of the IMD or OX layer 108.

In some suitable embodiments, at a next step 1014, a suitable material removal process is applied to remove those portions of the layer 114, the ferroelectric layer 102 and the first barrier metal layer 112 extending outside the hole or via 108a and covering the top surface of 108′ of the IMD or OX layer 108. In some suitable embodiments, this material removal process includes applying Chemical Mechanical Polishing (CMP). In practice, the applied CMP uses a combination of chemical and mechanical forces to achieve material removal. For example, an abrasive and corrosive chemical slurry (for example, a colloid) or the like is applied to the surface from which material is to be removed, for example, with a polishing pad or the like that is rotated with respect to or otherwise rubbed on and/or over the surface. The slurry in conjunction with the polishing pad selectively removes material from and/or planarizes the surface to which the CMP is applied. While CMP is a suitable approach, other techniques are for removal of those portions of the layer 114, the ferroelectric layer 102 and the first barrier metal layer 112 extending outside the hole or via 108a and covering the top surface of 108′ of the IMD or OX layer 108 are contemplated, such as mechanical polishing, or wet or dry etching. The configuration or state of the FeRAM cell construction following step 1014 is shown in FIG. 4D. In some suitable embodiments, dry plasma etching or other like etching techniques are not used for pattering and/or removal of the ferroelectric layer 102.

At a next step 1016 as shown in FIG. 3, in some suitable embodiments, the second ESL layer 118 is deposited, grown and/or otherwise formed over the surface to which the CMP was applied in step 1014. Accordingly, the configuration or state of the FeRAM cell construction following step 1016 is shown in FIG. 4E.

At a next step 1018 as shown in FIG. 3, in some suitable embodiments, the low-k material layer 116 is deposited, grown and/or otherwise formed and patterned over the second ESL 118. Suitably, patterning of the low-k material layer 116 may include creating the opening in which the top electrode 106 is to be formed. For example, the trench region 116a and the via 116b may be formed using one or more suitable photolithography processes employing appropriate masks and etching or other like material removal processes. In some suitable embodiments, the trench 116a and the via 116 may be formed by separate suitable etches or material removal process steps, or the etches or other material removal processes forming each of the trench 116a and via 116b may be sub-steps of a given process step, or otherwise. Accordingly, the configuration or state of the FeRAM cell construction following step 1018 is shown in FIG. 4F.

At a next step 1020 as shown in FIG. 3, in some suitable embodiments, an opening is created in the second ESL 118, for example, beneath the via 116b and over an upper surface 114a of the layer 114 filling in the remainder of the via 108a, thereby exposing the upper surface 114a of the layer 114. Suitably, step 1020 may include an appropriate etch or other like material removal process. Accordingly, the configuration or state of the FeRAM cell construction following step 1018 is shown in FIG. 4G.

At a next step 1022 as shown in FIG. 3, in some suitable embodiments, the top electrode structure is created. For example, step 1022 may include providing the second barrier metal layer 120 which is deposited, grown and/or otherwise formed over the low-k material layer 116 and depositing, growing and/or otherwise forming the top electrode 106 over the second barrier metal layer 120. For example, the second barrier metal layer 120 is created within the opening formed in the low-k material layer 116 such that the various wall(s) and/or sides 116′ defining the trench 116a and/or via are covered by the second barrier metal layer 120. Further, the second barrier metal layer 120 contacts the exposed upper surface 114a of the layer 114 through the opening formed in the second ESL 118 at step 1020. Suitably, the top electrode 106 is deposited, grown and/or otherwise formed to fill-in the remainder of the trench 116 and/or via 116b over the second barrier metal layer 120. In practice, a portion of the second barrier metal layer 120 and/or a portion of the material forming the top electrode 106 may initially extend out of and/or beyond the trench 116a, for example, over a top surface of the low-k material layer 116, and these portions same may be suitably eliminated by way of an appropriate material removal process, for example, such as CMP, etching, etc. Accordingly, following step 1022, manufacture of the FeRAM cell 100 is essentially complete and the configuration or state of the FeRAM cell construction is essentially as shown in FIG. 1.

In some embodiments, the various steps of the manufacturing process 1000 may be carried out in the process chamber(s) of one or more suitable computer controlled and/or programmable semiconductor manufacturing tools. A controller regulating and/or controlling the respective tools may be programmed, instructed and/or otherwise provisioned to cause the tool to execute the various steps. Suitably, the controller may be implemented via hardware, software, firmware or a combination thereof. In particular, one or more controllers may be embodied by processors, electrical circuits, computers and/or other electronic data processing devices that are configured and/or otherwise provisioned to perform one or more of the tasks, steps, processes, methods and/or functions described herein. For example, a processor, computer, server or other electronic data processing device embodying a controller may be provided, supplied and/or programmed with a suitable listing of code (e.g., such as source code, interpretive code, object code, directly executable code, and so forth) or other like instructions or software or firmware, such that when run and/or executed by the computer or other electronic data processing device one or more of the tasks, steps, processes, methods and/or functions described herein are completed or otherwise performed. Suitably, the listing of code or other like instructions or software or firmware is implemented as and/or recorded, stored, contained or included in and/or on a non-transitory computer and/or machine readable storage medium or media so as to be providable to and/or executable by the computer or other electronic data processing device. For example, suitable storage mediums and/or media can include but are not limited to: floppy disks, flexible disks, hard disks, magnetic tape, or any other magnetic storage medium or media, CD-ROM, DVD, optical disks, or any other optical medium or media, a RAM, a ROM, a PROM, an EPROM, a FLASH-EPROM, or other memory or chip or cartridge, or any other tangible medium or media from which a computer or machine or electronic data processing device can read and use. In essence, as used herein, non-transitory computer-readable and/or machine-readable mediums and/or media comprise all computer-readable and/or machine-readable mediums and/or media except for a transitory, propagating signal.

In general, any one or more of the particular tasks, steps, processes, methods, functions, elements and/or components described herein may be implemented on and/or embodiment in one or more general purpose computers, special purpose computer(s), a programmed microprocessor or microcontroller and peripheral integrated circuit elements, an ASIC or other integrated circuit, a digital signal processor, a hardwired electronic or logic circuit such as a discrete element circuit, a programmable logic device such as a PLD, PLA, FPGA, Graphical card CPU (GPU), or PAL, or the like. In general, any device, capable of implementing a finite state machine that is in turn capable of implementing the respective tasks, steps, processes, methods and/or functions described herein can be used.

In the following, some further illustrative embodiments are described.

In some embodiments, a method of manufacturing a ferroelectric random-access memory device includes: forming a first electrode; forming an intermetal dielectric layer over the first electrode, the intermetal dielectric layer having a first surface on a first side of the intermetal dielectric layer which is distal from the first electrode and a second surface on a second side of the intermetal dielectric layer which is proximate to the first electrode; creating a via extending through a thickness of the intermetal dielectric layer, the via being aligned with the first electrode there beneath and having a side wall which extends from the first surface of the intermetal dielectric layer to the second surface of the intermetal dielectric layer; depositing a ferroelectric material over the intermetal dielectric layer such that a ferroelectric layer is formed, including a first part arranged within the via and a second part extending laterally out from the via over the first surface of the intermetal dielectric layer; and removing the second part of the ferroelectric layer from over the first surface of the intermetal dielectric layer.

In some further embodiments, the method further includes forming a second electrode on the first side of the intermetal dielectric layer opposite the first electrode such that at least the first part of the ferroelectric layer is arranged between the first and second electrodes.

In still additional embodiments, the method further includes forming a barrier metal layer interposed between at least the first part of the ferroelectric layer and the side wall of the via formed in the intermetal dielectric layer, said barrier metal layer contacting a first surface of the first electrode.

In some embodiments, the method further includes: forming an etch stop layer between the intermetal dielectric layer and the first electrode; and forming an opening in the etch stop layer exposing the first surface of the first electrode to the via such that the barrier layer contacts the first surface of the first electrode through said opening.

In yet further embodiments, after forming the barrier metal and ferroelectric layers, a portion of the via formed in the intermetal dielectric layer remains unoccupied by the barrier metal and ferroelectric layers, and the method further includes: filling the remaining unoccupied portion of the via with a metal

In some further embodiments, application of the chemical mechanical polishing planarizes the metal, barrier metal layer and the ferroelectric layer such that ends thereof are made co-planar with the first surface of the intermetal dielectric layer.

In some embodiments, the ferroelectric material includes at least one of hafnium-zirconium oxide, zirconium oxide and barium titanate.

In yet further embodiments, the barrier metal layer comprises at least one of tantalum, tantalum nitride, ruthenium, titanium, titanium nitride, tungsten nitride and cobalt.

In some embodiments, the method further includes establishing an electrically conductive interconnect between the first electrode and a gate of a field-effect transistor.

In some further embodiments, a method of manufacturing a ferroelectric random-access memory cell includes: depositing an electrically insulating oxide layer over a bottom electrode, the oxide layer having a first surface on a first side of the oxide layer which is distal from the bottom electrode and a second surface on a second side of the oxide layer which is proximate to the bottom electrode; creating a hole extending through a thickness of the oxide layer, the hole being aligned with the bottom electrode and having a side wall which extends between the first surface of the oxide layer and the second surface of the oxide layer; depositing a barrier metal layer over the oxide layer on the first side thereof such that at least a first portion of the barrier metal layer is arranged within the hole and contacts a first surface of the bottom electrode; depositing a ferroelectric layer over the barrier metal layer such that at least a first portion of the ferroelectric layer is arranged within the hole with the first portion of the barrier metal layer being interposed between the side wall of the hole and the first portion of the ferroelectric layer; and depositing a metal layer over the ferroelectric layer such that at least a first portion of the metal layer fills a portion of the hole not occupied by the barrier metal and ferroelectric layers, the metal layer contacting a top electrode formed on the second side of the oxide layer opposite the bottom electrode with at least the first potion of the ferroelectric layer being arranged between the top and bottom electrodes.

In still further embodiments, the deposited barrier metal layer includes a second portion extending laterally from the hole over the first surface of the oxide layer; the deposited ferroelectric layer includes a second portion extending laterally from the hole over the second portion of barrier metal layer; and the deposited metal layer includes a second portion extending laterally from the hole over the second portion of the ferroelectric layer.

In yet additional embodiments, the method further includes removing the second portion of the barrier metal layer, the second portion of the ferroelectric layer and the second portion of the metal layer by applying chemical mechanical polishing on the first side of the oxide layer.

In some further embodiments, the thickness of the oxide layer is in a range of between 80 nm and 120 nm, inclusive.

In some additional embodiments, a thickness of the deposited barrier metal layer is 30 A.

In some embodiments, a thickness of the deposited ferroelectric layer is less than 50 A.

In some embodiments, the ferroelectric layer comprises at least one of hafnium-zirconium oxide, zirconium oxide and barium titanate.

In some further embodiments, the barrier metal layer comprises at least one of tantalum, tantalum nitride, ruthenium, titanium, titanium nitride, tungsten nitride and cobalt.

In still further embodiments, a ferroelectric random-access memory device includes: a first electrode; a second electrode; an intermetal dielectric layer arranged between the first and second electrodes, the intermetal dielectric layer having a via formed therein extending through a thickness of the intermetal dielectric layer, the via being aligned with the first electrode and having a side wall which extends between a first surface of the intermetal dielectric layer proximate to the first electrode and a second surface of the intermetal dielectric layer distal from the first electrode; a barrier metal layer arranged within the via and contacting a first surface of the first electrode aligned beneath the via; a ferroelectric layer arranged within the via such the barrier metal layer is interposed between the side wall of the via and the ferroelectric layer; and a metal disposed within a portion of the via not occupied by the barrier metal and ferroelectric layers, the metal contacting the second electrode.

In yet further embodiments, the device further includes a low-k material layer arranged over the second surface of the intermetal dielectric layer, the low-k material layer having an opening therethrough in which the second electrode is arranged.

In still one more embodiment, the device further includes a field-effect transistor having a gate electrode to which the first electrode is electrically connected.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a ferroelectric random-access memory device, said method comprising:
forming a first electrode;
forming an intermetal dielectric layer over the first electrode, said intermetal dielectric layer having a first surface on a first side of the intermetal dielectric layer which is distal from the first electrode and a second surface on a second side of the intermetal dielectric layer which is proximate to the first electrode;
creating a via extending through a thickness of the intermetal dielectric layer, said via being aligned with the first electrode there beneath and having a side wall which extends from the first surface of the intermetal dielectric layer to the second surface of the intermetal dielectric layer;
depositing a ferroelectric material over the intermetal dielectric layer such that a ferroelectric layer is formed, including a first part arranged within the via and a second part extending laterally out from the via over the first surface of the intermetal dielectric layer; and
removing the second part of the ferroelectric layer from over the first surface of the intermetal dielectric layer.

2. The method of claim 1, further comprising:
forming a second electrode on the first side of the intermetal dielectric layer opposite the first electrode such that at least the first part of the ferroelectric layer is arranged between the first and second electrodes.

3. The method of claim 1, further comprising:
forming a barrier metal layer interposed between at least the first part of the ferroelectric layer and the side wall of the via formed in the intermetal dielectric layer, said barrier metal layer contacting a first surface of the first electrode.

4. The method of claim 3, further comprising:
forming an etch stop layer between the intermetal dielectric layer and the first electrode; and
forming an opening in the etch stop layer exposing the first surface of the first electrode to the via such that the barrier layer contacts the first surface of the first electrode through said opening.

5. The method of claim 3, wherein after forming the barrier metal and ferroelectric layers, a portion of the via formed in the intermetal dielectric layer remains unoccupied by the barrier metal and ferroelectric layers, and the method further comprises:
filling the remaining unoccupied portion of the via with a metal.

6. The method of claim 5, wherein application of the chemical mechanical polishing planarizes the metal, barrier metal layer and the ferroelectric layer such that ends thereof are made co-planar with the first surface of the intermetal dielectric layer.

7. The method of claim 1, wherein the ferroelectric material includes at least one of hafnium-zirconium oxide, zirconium oxide and barium titanate.

8. The method of claim 4, wherein the barrier metal layer comprises at least one of tantalum, tantalum nitride, ruthenium, titanium, titanium nitride, tungsten nitride and cobalt.

9. The method of claim 1, further comprising:
establishing an electrically conductive interconnect between the first electrode and a gate of a field-effect transistor.

10. A method of manufacturing a ferroelectric random-access memory cell comprising:
depositing an electrically insulating oxide layer over a bottom electrode, said oxide layer having a first surface on a first side of the oxide layer which is distal from the bottom electrode and a second surface on a second side of the oxide layer which is proximate to the bottom electrode;
creating a hole extending through a thickness of the oxide layer, said hole being aligned with the bottom electrode and having a side wall which extends between the first surface of the oxide layer and the second surface of the oxide layer;
depositing a barrier metal layer over the oxide layer on the first side thereof such that at least a first portion of the barrier metal layer is arranged within the hole and contacts a first surface of the bottom electrode;
depositing a ferroelectric layer over the barrier metal layer such that at least a first portion of the ferroelectric layer is arranged within the hole with the first portion of the barrier metal layer being interposed between the side wall of the hole and the first portion of the ferroelectric layer; and
depositing a metal layer over the ferroelectric layer such that at least a first portion of the metal layer fills a portion of the hole not occupied by the barrier metal and ferroelectric layers, said metal layer contacting a top electrode formed on the second side of the oxide layer opposite the bottom electrode with at least the first potion of the ferroelectric layer being arranged between the top and bottom electrodes.

11. The method of claim 10, wherein:
the deposited barrier metal layer includes a second portion extending laterally from the hole over the first surface of the oxide layer;
the deposited ferroelectric layer includes a second portion extending laterally from the hole over the second portion of barrier metal layer; and
the deposited metal layer includes a second portion extending laterally from the hole over the second portion of the ferroelectric layer.

12. The method of claim 11, said method further comprising:
removing the second portion of the barrier metal layer, the second portion of the ferroelectric layer and the second portion of the metal layer by applying chemical mechanical polishing on the first side of the oxide layer.

13. The method of claim 10, wherein the thickness of the oxide layer is in a range of between 80 nm and 120 nm, inclusive.

14. The method of claim 10, wherein a thickness of the deposited barrier metal layer is 30 A.

15. The method of claim 10, wherein a thickness of the deposited ferroelectric layer is less than 50 A.

16. The method of claim 10, wherein the ferroelectric layer comprises at least one of hafnium-zirconium oxide, zirconium oxide and barium titanate.

17. The method of claim 10, wherein the barrier metal layer comprises at least one of tantalum, tantalum nitride, ruthenium, titanium, titanium nitride, tungsten nitride and cobalt.

18. A ferroelectric random-access memory device comprising:
a first electrode;
a second electrode;
an intermetal dielectric layer arranged between the first and second electrodes, said intermetal dielectric layer having a via formed therein extending through a thickness of the intermetal dielectric layer, said via being aligned with the first electrode and having a side wall which extends between a first surface of the intermetal dielectric layer proximate to the first electrode and a second surface of the intermetal dielectric layer distal from the first electrode;
a barrier metal layer arranged within the via and contacting a first surface of the first electrode aligned beneath the via;
a ferroelectric layer arranged within the via such the barrier metal layer is interposed between the side wall of the via and the ferroelectric layer; and
a metal disposed within a portion of the via not occupied by the barrier metal and ferroelectric layers, said metal contacting the second electrode.

19. The ferroelectric random-access memory device of claim 18, further comprising:
a low-k material layer arranged over the second surface of the intermetal dielectric layer, said low-k material layer having an opening therethrough in which the second electrode is arranged.

20. The ferroelectric random-access memory device of claim 18, further comprising:
a field-effect transistor having a gate electrode to which the first electrode is electrically connected.
